(19) United States
(12) Patent Application Publication
(10) Pub. No.: US 2019/0264070 A1
(43) Pub. Date: Aug. 29, 2019

(54) THERMALLY CONDUCTIVE PASTE AND ELECTRONIC DEVICE

(71) Applicant: SUMITOMO BAKELITE CO., LTD., Tokyo (JP)

(72) Inventor: Koji MAKIHARA, Tokyo (JP)

(73) Assignee: SUMITOMO BAKELITE CO., LTD., Tokyo (JP)

(21) Appl. No.: 16/346,045

(22) PCT Filed: Oct. 24, 2017
(86) PCT No.: PCT/JP2017/038315

§ 371 Date: Apr. 29, 2019

(30) Foreign Application Priority Data
Oct. 31, 2016 (JP) 2016-213664

(51) Int. Cl. C09J 9/02; C09J 163/00; C08K 3/013; C08K 3/22; H01L 21/52

(52) U.S. Cl. CPC C09J 9/02; C09J 163/00; C08K 2201/001; C08K 3/22; H01L 21/52; C08K 3/013

(57) ABSTRACT

A thermally conductive paste of the present invention includes a thermosetting resin and a thermally conductive filler, a ratio of a wet spreading area is 90% or more, and when an average particle size D₅₀ of the thermally conductive filler is referred to as D, a viscosity of the thermally conductive paste excluding the thermally conductive filler at room temperature 25° C. is referred to as η, and a degree of sedimentation of the thermally conductive filler in the thermally conductive paste is referred to as S=D²/η, S is 8 [10⁻¹²·m³·s/kg] or more and 900 [10⁻¹²·m³·s/kg] or less.

### TECHNICAL FIELD

The present invention relates to a thermally conductive paste and an electronic device.

### BACKGROUND ART

Various developments have been made in hitherto known thermally conductive pastes used for adhering a semiconductor chip to a frame for the purpose of improving thermal conductivity. As this type of technique, there is a technique described in Patent Document 1. According to this document, an acrylic resin-containing highly thermally conductive paste containing 90 mass % of silver is described (examples and the like of Patent Document 1).

### RELATED DOCUMENT

### Patent Document

[Patent Document 1] Japanese Laid-open Patent Publication No. 2004-140170

### SUMMARY OF THE INVENTION

### Technical Problem

However, it has been determined that there is room for improvement in the thermally conductive paste described in the above document in terms of storage stability and handleability.

### Solution to Problem

The present inventors focused on the state of a thermally conductive paste, studied each case, and found that in a thermally conductive paste after storage, separation of a thermally conductive filler occurs, and stringiness occurs in the thermally conductive paste during use.

For example, when the amount of the thermally conductive filler in the thermally conductive paste is increased for the purpose of improving thermal conductivity, an increase in silver size and a reduction in the molecular weight of the resin are required so that the thermally conductive paste does not have a high viscosity. Therefore, in the thermally conductive paste, the thermally conductive filler may be easily separated.

On the other hand, when the molecular weight of the resin is increased for the purpose of suppressing separation of the thermally conductive filler, in contrast, stringiness may occur during use.

As described above, it was found that there is a trade-off relationship between different cases regarding the state of the thermally conductive paste, that is, between a case of storage and a case of use.

As a result of intensive investigation based on the above findings, the present inventors found that the state of the thermally conductive paste during storage can be evaluated by the degree of spread of the thermally conductive paste, and the state of the thermally conductive paste during use can be evaluated by the degree of sedimentation of the thermally conductive paste. In addition, it was found that by increasing the degree of spread of the thermally conductive paste and causing the degree of sedimentation of the thermally conductive filler to have an optimal value, the storage stability and handleability can be improved, and the present invention was completed.

According to the present invention, there is provided a thermally conductive paste including: a thermosetting resin; and a thermally conductive filler, in which a ratio of a wet spreading area calculated by the following measurement method is 90% or more, and when an average particle size D₅₀ of the thermally conductive filler is referred to as D, a viscosity of the thermally conductive paste excluding the thermally conductive filler at room temperature 25° C. is referred to as D, and a degree of sedimentation of the thermally conductive filler in the thermally conductive paste is referred to as S=D²/η, S is 8 [10⁻¹²·m³·s/kg] or more and 900 [10⁻¹²·m³·s/kg] or less.

(Measurement Method of Wet Spreading Area)

The thermally conductive paste is applied to a surface of a lead frame so as to intersect diagonally. Next, the resultant is statically left at room temperature 25° C. for 8 hours. Next, a 2 mm×2 mm silicon bare chip is mounted on the lead frame through the thermally conductive paste, and thereafter the ratio of the wet spreading area of the thermally conductive paste to the surface of the silicon bare chip is calculated.

In addition, according to the present invention, there is provided an electronic device including: a cured product of the thermally conductive paste.

### Advantageous Effects of Invention

According to the present invention, there are provided a thermally conductive paste excellent in storage stability and handleability, and an electronic device using the same.

### BRIEF DESCRIPTION OF THE DRAWINGS

The above and other objects, advantages and features will be more apparent from the following description of embodiments taken in conjunction with the accompanying drawings.

FIG. 1 is a cross-sectional view illustrating an example of a semiconductor device according to an embodiment.

### DESCRIPTION OF EMBODIMENTS

Hereinafter, an embodiment will be described with reference to the drawings. In all the drawings, like elements are denoted by like reference numerals, and the description thereof will not be repeated as appropriate.

A thermally conductive paste of this embodiment may contain a thermosetting resin, and a thermally conductive filler.

In the thermally conductive paste of this embodiment, the ratio of the wet spreading area calculated by the following measurement method can be 90% or more. In addition, when the degree of sedimentation of the thermally conductive filler in the thermally conductive paste of this embodiment is referred to as S=D²/η, S can be 8 [10⁻¹²·m³·s/kg] or more and 900 [10⁻¹²·m³·s/kg] or less.

In this embodiment, the average particle size D₅₀ of the thermally conductive filler is referred to as D, and the viscosity of the thermally conductive paste excluding the thermally conductive filler at room temperature 25° C. is referred to as η.

In addition, in this embodiment, as a measurement method of the wet spreading area, the following method can be used. First, the thermally conductive paste is applied to the surface of a lead frame so as to intersect diagonally. Next, the resultant is statically left at room temperature 25° C. for 8 hours. Next, a silicon bare chip having a surface of 2 mm×2 mm is mounted on the lead frame through the thermally conductive paste, and thereafter the ratio (%) of the wet spreading area of the thermally conductive paste to the surface area of the silicon bare chip is calculated.

The present inventors found that the state of the thermally conductive paste during storage can be evaluated by using the wet spreading area of the thermally conductive paste as an index, and the state of the thermally conductive paste during use can be appropriately evaluated by using a sedimentation index of the thermally conductive filler, which is expressed by the relationship between the particle size of the thermally conductive filler and a resin viscosity.

As a result of intensive investigation based on the above findings, the present inventors determined that by controlling the ratio of the wet spreading area to 90% or more and controlling a degree of sedimentation S of the thermally conductive filler to 8 [10⁻¹²·m³·s/kg] or more and 900 [10⁻¹²·m³·s/kg] or less, separation of the thermally conductive filler can be suppressed, the stringiness of the thermally conductive filler can be suppressed, and the storage stability and handleability can be improved, and completed the present invention.

According to the thermally conductive paste of this embodiment, an appropriate paste state can be maintained during storage and during use. Therefore, characteristics such as thermal conductivity and metal adhesion can be made desirable. In addition, according to this embodiment, the characteristics of the thermally conductive paste can be realized as designed even after storage.

In this embodiment, by appropriately selecting, for example, kinds and mixing amounts of components contained in the thermally conductive paste, a preparation method of the thermally conductive paste, and the like, it is possible to control the wet spreading area and the degree of sedimentation S. Among these, for example, using a low molecular weight monomer as an acrylic compound and the thermosetting resin, reducing the particle size and amount of the thermally conductive filler, and the like are adopted as elements for causing the wet spreading area and the degree of sedimentation S to be in desired numerical value ranges.

According to this embodiment, a thermally conductive paste excellent in thermal conductivity and storage stability can be realized.

The thermally conductive paste of this embodiment may be used as an adhesion layer for bonding a base material such as a printed circuit board and an electronic component such as a semiconductor element. That is, the resin adhesion layer made of the cured product of the thermally conductive paste of this embodiment can be used as a die-attach material. By using the cured product of the thermally conductive paste of this embodiment, the thermally conductive filler is appropriately dispersed, and thus the heat dissipation properties of the electronic component are excellent. Therefore, a die-attach material excellent in metal adhesion (metal adhesion after moisture absorption) between the electronic component and the base material can be realized.

Furthermore, even in a case where the amount of the thermally conductive filler in the thermally conductive paste of this embodiment is low, the thermal conductivity can be kept high. That is, the thermally conductive paste containing the heat conductive filler in a low amount can realize high thermal conductivity. As an example, even in a case where the amount of the thermally conductive filler is 80 mass % or less, a thermal conductivity of 5 W/mK or more, and more preferably 10 W/mK or more can be realized.

Hereinafter, components of the thermally conductive paste of this embodiment will be described.

(Thermosetting Resin)

As the thermosetting resin contained in the thermally conductive paste, a general thermosetting resin which forms a three-dimensional network structure by heating can be used. In this embodiment, the thermosetting resin is not particularly limited, but may contain, for example, one or two or more selected from a cyanate resin, an epoxy resin, a resin having two or more radically polymerizable carbon-carbon double bonds in one molecule, and a maleimide resin. Among these, from the viewpoint of improving the adhesion of the thermally conductive paste, it is particularly preferable that an epoxy resin is contained.

As the epoxy resin used as the thermosetting resin, monomers, oligomers, and polymers having two or more glycidyl groups in one molecule can be used, and the molecular weight and molecular structure thereof are not particularly limited. Examples of the epoxy resin in this embodiment include: a biphenyl type epoxy resin; a bisphenol type epoxy resin such as a bisphenol A type epoxy resin, a bisphenol F type epoxy resin, and a tetramethyl bisphenol F type epoxy resin; a stilbene type epoxy resin; a novolac type epoxy resin such as a phenol novolac type epoxy resin and a cresol novolac type epoxy resin; a multifunctional epoxy resin such as a triphenol methane type epoxy resin and an alkyl-modified triphenol methane type epoxy resin; an aralkyl type epoxy resin such as a phenol aralkyl type epoxy resin having a phenylene skeleton and a phenol aralkyl type epoxy resin having a biphenylene skeleton; a naphthol type epoxy resin such as a dihydroxynaphthalene type epoxy resin and an epoxy resin obtained by glycidyl etherification of a dimer of dihydroxynaphthalene; a triazine nucleus-containing epoxy resin such as triglycidyl isocyanurate and monoallyl diglycidyl isocyanurate; and a bridged cyclic hydrocarbon compound-modified phenol type epoxy resin such as a dicyclopentadiene-modified phenol type epoxy resin. Furthermore, as the epoxy resin, for example, among compounds having two or more glycidyl groups in one molecule, bifunctional ones obtained by epoxidation of a bisphenol compound such as bisphenol A, bisphenol F, and biphenol or derivatives thereof, a diol having an alicyclic structure such as hydrogenated bisphenol A, hydrogenated bisphenol F, hydrogenated biphenol, cyclohexanediol, cyclohexanedimethanol, and cyclohexanediethanol or derivatives thereof, an aliphatic diol such as butanediol, hexanediol, octanediol, nonanediol, and decanediol or derivatives thereof, and the like, and trifunctional ones having a trihydroxyphenylmethane skeleton and an aminophenol skeleton, can also be used. The epoxy resin as the thermosetting resin may contain one or two or more selected from those exemplified above.

Among these, from the viewpoint of improving application workability and adhesion, it is more preferable to include a bisphenol type epoxy resin, and it is particularly preferable to include a bisphenol F type epoxy resin. In addition, in this embodiment, from the viewpoint of more effectively improving the application workability, it is more preferable to include a liquid epoxy resin that is liquid at room temperature (25° C.)

The cyanate resin used as the thermosetting resin is not particularly limited, but may contain, for example, one or two or more selected from 1,3-dicyanatobenzene, 1,4-dicyanatobenzene, 1,3,5-tricyanatobenzene, 1,3-dicyanatonaphthalene, 1,4-dicyanatonaphthalene, 1,6-dicyanatonaphthalene, 1,8-dicyanatonaphthalene, 2,6-dicyanatonaphthalene, 2,7-dicyanatonaphthalene, 1,3,6-tricyanatonaphthalene, 4,4′-disocyanatobiphenyl, bis(4-cyanatophenyl)methane, bis(3,5-dimethyl-4-cyanatophenyl)methane, 2,2-bis(4-cyanatophenyl)propane, 2,2-bis(3,5-dibromo-4-cyanatophenyl)propane, bis(4-cyanatophenyl)ether, bis(4-cyanatophenyl)thioether, bis(4-cyanatophenyl)sulfone, tris(4-cyanatophenyl)phosphite, tris(4-cyanatophenyl)phosphate, cyanates obtained by reaction of novolac resins with cyanogen halides, and prepolymers having a triazine ring formed by trimerization of cyanate groups of these polyfunctional cyanate resins. The prepolymers can be obtained by polymerization of the polyfunctional cyanate resin monomer with a catalyst such as an acid such as a mineral acid and a Lewis acid, a base such as sodium alcoholate and a tertiary amine, or a salt such as sodium carbonate.

As the resin having two or more radically polymerizable carbon-carbon double bonds in one molecule, which is used as the thermosetting resin, for example, a radically polymerizable acrylic resin having two or more (meth)acryloyl groups in a molecule can be used. In this embodiment, the acrylic resin is a polyether, a polyester, a polycarbonate, or a poly (meth)acrylate having a molecular weight of 500 to 10,000 and may include a compound having a (meth)acrylic group. In a case where the resin having two or more radically polymerizable carbon-carbon double bonds in one molecule is used as the thermosetting resin, the thermally conductive paste may contain, for example, a polymerization initiator such as a thermal radical polymerization initiator.

The maleimide resin used as the thermosetting resin is not particularly limited, but may contain, for example, one or two or more selected from bismaleimide resins such as N,N′-(4,4-diphenylmethane)bismaleimide, bis(3-ethyl-5-methyl-4-maleimidophenyl)methane, and 2,2-bis[4-(4-maleimidophenoxy)phenyl]propane.

The thermosetting resin according to this embodiment may contain an epoxy resin having a biphenyl skeleton (biphenyl type epoxy resin) as the resin having a biphenyl skeleton. Accordingly, the thermal conductivity and the metal adhesion of the thermally conductive paste can be improved.

The structure of the epoxy resin having a biphenyl skeleton is not particularly limited as long as the structure has a biphenyl skeleton in its molecular structure and has two or more epoxy groups. However, for example, a bifunctional epoxy resin obtained by treating biphenol or its derivative with epichlorohydrin, a phenol aralkyl type epoxy resin having a biphenylene skeleton, and a naphthol aralkyl type epoxy resin having a biphenylene skeleton can be exemplified, and these may be used singly or in combination. Among them, those having two epoxy groups in a molecule are excellent in the improvement in heat resistance and thus are particularly preferable. Examples of the epoxy resin include: a bifunctional epoxy resin obtained by treating a biphenol derivative such as a biphenyl type epoxy resin and a tetramethylbiphenyl type epoxy resin with epichlorohydrin; among phenol aralkyl type epoxy resins having a biphenylene skeleton, those having two epoxy groups (sometimes expressed as having two phenol nuclei); and among naphthol aralkyl type resins having a biphenylene skeleton, those having two epoxy groups.

The weight-average molecular weight of the thermosetting resin of this embodiment may be, for example, 100 or more and 500 or less, and is preferably 150 or more and 450 or less, and more preferably 200 or more and 400 or less.

In this embodiment, the amount of the thermosetting resin in the thermally conductive paste is, for example, preferably 5 mass % or more, more preferably 6 mass % or more, and even more preferably 7 mass % or more with respect to the entire thermally conductive paste. Accordingly, the fluidity of the thermally conductive paste can be improved, and the application workability can be further improved. On the other hand, the amount of the thermosetting resin in the thermally conductive paste is, for example, preferably 30 mass % or less, more preferably 25 mass % or less, and even more preferably 15 mass % or less with respect to the entire thermally conductive paste. Accordingly, the reflow resistance and moisture resistance of the adhesion layer formed by using the thermally conductive paste can be improved.

(Acrylic Compound)

The thermally conductive paste of this embodiment may contain the acrylic compound.

The acrylic compound according to this embodiment preferably contains a (meth)acrylic monomer. In this embodiment, the (meth)acrylic monomer represents an acrylate monomer, a methacrylate monomer or a mixture thereof, and represents a monomer having at least one functional group (acrylic group or methacrylic group).

In this embodiment, the (meth)acrylic monomer may be a monomer having two or more functional groups. Accordingly, the metal adhesion can be improved.

The (meth)acrylic monomer according to this embodiment is different from an acrylic polymer obtained by polymerization of monomers, and is a monomer having at least one ethylenically unsaturated double bond. The molecular weight of the (meth)acrylic monomer is not particularly limited, and for example, the lower limit thereof may be 150 or more, and is preferably 160 or more, and more preferably 180 or more, whereas the upper limit thereof may be 2000 or less, and is preferably 1000 or less, and more preferably 600 or less.

The (meth)acrylic monomer according to this embodiment is different from an acrylic polymer obtained by polymerization of monomers, and is a monomer having at least one ethylenically unsaturated double bond. The molecular weight of the (meth)acrylic monomer is not particularly limited, and for example, the lower limit thereof may be 150 or more, and is preferably 160 or more, and more preferably 180 or more, whereas the upper limit thereof may be 2000 or less, and is preferably 1000 or less, and more preferably 600 or less.

Examples of the bifunctional (meth)acrylic monomer include glycerin di(meth)acrylate, trimethylolpropane di(meth)acrylate, pentaerythritol di(meth)acrylate, zinc di(meth)acrylate, ethylene glycol di(meth)acrylate, propylene glycol di(meth)acrylate, 1,4-butanediol di(meth)acrylate, 1,6-hexanediol di(meth)acrylate, 1,9-nonanediol di(meth)acrylate, 1,3-butanediol di(meth)acrylate, 1,10-decanediol di(meth)acrylate, and tetramethylene glycol di(meth)acrylate. These may be used singly or in combination of two or more.

The (meth)acrylic monomer according to this embodiment can contain other acrylic compounds in addition to the (meth)acrylic monomer. Examples of other acrylic compounds include monomers and oligomers of monofunctional acrylate, polyfunctional acrylate, monofunctional methacrylate, polyfunctional methacrylate, urethane acrylate, urethane methacrylate, epoxy acrylate, epoxy methacrylate, polyester acrylate, or urea acrylate, and mixtures thereof. One or two or more thereof may be used.

Examples of other acrylic compounds include (meth)acrylates having a hydroxyl group such as 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, 4-hydroxybutyl (meth)acrylate, 1,2-cyclohexanediol mono(meth)acrylate, 1,3-cyclohexanediol mono(meth)acrylate, 1,4-cyclohexanediol mono(meth)acrylate, 1,2-cyclohexanedimethanol mono(meth)acrylate, 1,3-cyclohexanedimethanol mono(meth)acrylate, 1,4-cyclohexanedimethanol mono(meth)acrylate, 1,2-cyclohexanediethanol mono(meth)acrylate, 1,3-cyclohexanediethanol mono(meth)acrylate, 1,4-cyclohexanediethanol mono(meth)acrylate, glycerin mono(meth)acrylate, trimethylolpropane mono(meth)acrylate, pentaerythritol mono(meth)acrylate, pentaerythritol tri(meth)acrylate, and neopentyl glycol mono(meth)acrylate, and (meth)acrylates having a carboxyl group obtained by reaction of the (meth)acrylates having a hydroxyl group with a dicarboxylic acid or derivatives thereof. Examples of the dicarboxylic acid which can be used herein include oxalic acid, malonic acid, succinic acid, glutaric acid, adipic acid, pimelic acid, suberic acid, azelaic acid, sebacic acid, maleic acid, fumaric acid, phthalic acid, tetrahydrophthalic acid, and hexahydrophthalic acid, and derivatives thereof.

In addition, as other acrylic compounds, for example, methyl (meth)acrylate, ethyl (meth)acrylate, n-butyl (meth)acrylate, isobutyl (meth)acrylate, tertiary-butyl (meth)acrylate, isodecyl (meth)acrylate, lauryl (meth)acrylate, tridecyl (meth)acrylate, cetyl (meth)acrylate, stearyl (meth)acrylate, isoamyl (meth)acrylate, isostearyl (meth)acrylate, behenyl (meth)acrylate, 2-ethylhexyl (meth)acrylate, other alkyl (meth)acrylates, cyclohexyl (meth)acrylate, tertiary-butyl cyclohexyl (meth)acrylate, tetrahydrofurfuryl (meth)acrylate, benzyl (meth)acrylate, phenoxyethyl (meth)acrylate, isobornyl (meth)acrylate, glycidyl (meth)acrylate, trimethylolpropane tri(meth)acrylate, zinc mono(meth)acrylate, dimethylaminoethyl (meth)acrylate, diethylaminoethyl (meth)acrylate, neopentyl glycol (meth)acrylate, trifluoroethyl (meth)acrylate, 2,2,3,3-tetrafluoropropyl (meth)acrylate, 2,2,3,3,4,4-hexafluorobutyl (meth)acrylate, perfluorooctyl (meth)acrylate, perfluorooctylethyl (meth)acrylate, methoxyethyl (meth)acrylate, butoxyethyl (meth)acrylate, ethoxy diethylene glycol (meth)acrylate, methoxy polyalkylene glycol mono(meth)acrylate, octoxy polyalkylene glycol mono(meth)acrylate, lauroxy polyalkylene glycol mono(meth)acrylate, stearoxy polyalkylene glycol mono(meth)acrylate, allyloxy polyalkylene glycol mono(meth)acrylate, nonyl phenoxy polyalkylene glycol mono(meth)acrylate, N,N′-ethylenebis(meth)acrylamide, N,N′-methylenebis(meth)acrylamide, 1,2-di(meth)acrylamide ethylene glycol, di(meth)acryloyloxymethyl tricyclodecane, N-(meth)acryloyloxyethyl maleimide, N-(meth)acryloyloxyethyl hexahydrophthalimide, N-(meth)acryloyloxyethyl phthalimide, n-vinyl-2-pyrrolidone, styrene derivatives, and α-methylstyrene derivatives can be used.

In this embodiment, the lower limit of the amount of the (meth)acrylic monomer is, for example, 1 mass % or more, preferably 3 mass % or more, and more preferably 5 mass % or more with respect to the entire thermally conductive paste. Accordingly, ejection stability and metal adhesion can be enhanced. A reduction in viscosity can also be achieved. The upper limit of the amount of the (meth)acrylic monomer is, for example, 15 mass % or less, preferably 12 mass % or less, and more preferably 10 mass % or less with respect to the entire thermally conductive paste. Accordingly, a balance between various properties of the thermally conductive paste can be achieved.

(Thermally Conductive Filler)

The thermally conductive paste of this embodiment may contain the thermally conductive filler.

The thermally conductive filler is not particularly limited as long as the thermally conductive filler is a filler having excellent thermal conductivity, but the thermally conductive filler may contain, for example, a metal, an oxide, or a nitride.

Examples of the metal filler include metal powder such as silver powder, gold powder, and copper powder. Examples of the oxide filler include silicates such as talc, calcined clay, uncalcined clay, mica, and glass; oxide particles such as titanium oxide, alumina, magnesia, boehmite, silica, and fused silica, and hydroxide particles such as aluminum hydroxide, magnesium hydroxide, and calcium hydroxide. Examples of the nitride filler include nitride particles such as aluminum nitride, boron nitride, silicon nitride, and carbon nitride.

The thermally conductive filler of this embodiment may contain other inorganic fillers including: sulfates or sulfites such as barium sulfate, calcium sulfate, and calcium sulfite; borates such as zinc borate, barium metaborate, aluminum borate, calcium borate, and sodium borate; and titanates such as strontium titanate and barium titanate.

These may be used singly or in combination of two or more.

From the viewpoint of conductivity, it is preferable that the thermally conductive filler of this embodiment contains one or more selected from the group consisting of silver, copper, and alumina. Accordingly, the long-term workability can be improved.

The shape of the thermally conductive filler of this embodiment may be a flake shape, a spherical shape, or the like. Among these, a spherical shape is preferable from the viewpoint of the fluidity of the thermally conductive paste.

The lower limit of the average particle size D₅₀ of the thermally conductive filler may be, for example, 0.1 μm or more, and is preferably 0.3 μm or more and more preferably 0.5 μm or more. Accordingly, the thermal conductivity of the thermally conductive paste can be improved. On the other hand, the upper limit of the average particle size D₅₀ of the thermally conductive filler may be, for example, 10 μm or less, and is preferably 8 μm or less, and more preferably 5 μm or less. Thereby, the storage stability of the thermally conductive paste can be improved.

The lower limit of the average particle size D₉₅ of the thermally conductive filler may be, for example, 1 μm or more, and is preferably 2 μm or more, and more preferably 3 μm or more. Accordingly, the thermal conductivity of the thermally conductive paste can be improved. On the other hand, the upper limit of the average particle size D₉₅ of the thermally conductive filler may be, for example, 15 μm or less, and is preferably 13 μm or less, and more preferably 10 μm or less. Accordingly, the storage stability of the thermally conductive paste can be improved.

The average particle size of the thermally conductive filler can be measured by, for example, a laser diffraction scattering method, or a dynamic light scattering method.

In this embodiment, the amount of the thermally conductive filler in the thermally conductive paste is, for example, preferably 50 mass % or more, and more preferably 60 mass % or more with respect to the entire thermally conductive paste. Accordingly, the low thermal expansion, moisture resistance reliability, and reflow resistance of the adhesion layer formed using the thermally conductive paste can be more effectively improved. On the other hand, the amount of the thermally conductive filler in the thermally conductive paste is, for example, 88 mass % or less, preferably 83 mass % or less, and more preferably 80 mass % or less with respect to the entire thermally conductive paste. Accordingly, the fluidity of the thermally conductive paste can be improved, and the application workability and the uniformity of the adhesion layer can be improved.

(Curing Agent)

The thermally conductive paste may contain a curing agent. Accordingly, the curability of the thermally conductive paste can be improved. The curing agent may contain, for example, one or two or more selected from aliphatic amines, aromatic amines, dicyandiamide, dihydrazide compounds, acid anhydrides, and phenol compounds. Among these, it is particularly preferable to include at least one of dicyandiamide and phenol compounds from the viewpoint of improving the manufacturing stability.

Examples of the dihydrazide compounds used as the curing agent include carboxylic acid dihydrazides such as adipic acid dihydrazide, dodecanoic acid dihydrazide, isophthalic acid dihydrazide, and p-oxybenzoic acid dihydrazide. Examples of the acid anhydrides used as the curing agent include phthalic anhydride, tetrahydrophthalic anhydride, hexahydrophthalic anhydride, endomethylene tetrahydrophthalic anhydride, dodecenylsuccinic anhydride, a reaction product of maleic anhydride and polybutadiene, and a copolymer of maleic anhydride and styrene.

The phenol compound used as the curing agent is a compound having two or more phenolic hydroxyl groups in one molecule. More preferably, the number of phenolic hydroxyl groups in one molecule is 2 to 5, and particularly preferably, the number of phenolic hydroxyl groups in one molecule is 2 or 3. Accordingly, the application workability of the thermally conductive paste can be more effectively improved, and the properties of the cured product of the thermally conductive paste can be improved by forming a cross-linked structure during curing. The phenol compound may contain, for example, one or two or more selected from bisphenols such as bisphenol F, bisphenol A, bisphenol S, tetramethyl bisphenol A, tetramethyl bisphenol F, tetramethyl bisphenol S, dihydroxydiphenyl ether, dihydroxybenzophenone, tetramethyl biphenol, ethylidene bisphenol, methylethylidene bis(methyl phenol), cyclohexylidene bisphenol, and biphenol and derivatives thereof, trifunctional phenols such as tri(hydroxyphenyl)methane and tri(hydroxyphenyl)ethane and derivatives thereof, and compounds which are obtained by reaction of phenols such as phenol novolac and cresol novolac with formaldehyde and mainly binuclear or trinuclear and derivatives thereof. Among these, those containing bisphenols are more preferable, and those containing bisphenol F are particularly preferable.

In addition, the curing agent according to this embodiment may contain a phenol resin (phenol compound) having a biphenyl skeleton as the resin having a biphenyl skeleton. Accordingly, the thermal conductivity and the metal adhesion of the thermally conductive paste can be improved.

The structure of the phenol resin having a biphenyl skeleton is not particularly limited as long as the structure has a biphenyl skeleton in the molecular structure and has two or more phenol groups.

In this embodiment, the amount of the curing agent in the thermally conductive paste is preferably 0.5 mass % or more, and more preferably 1.0 mass % or more with respect to the entire thermally conductive paste. Accordingly, the curability of the thermally conductive paste can be more effectively improved. On the other hand, the amount of the curing agent in the thermally conductive paste is preferably 10 mass % or less, and more preferably 7 mass % or less with respect to the entire thermally conductive paste. Accordingly, the low thermal expansion, reflow resistance, and moisture resistance of the adhesion layer formed using the thermally conductive paste can be improved.

In this embodiment, the lower limit of the amount of the resin having a biphenyl skeleton is, for example, 1 mass % or more, preferably 1.5 mass % or more, and more preferably 2 mass % or more with respect to the entire thermally conductive paste. Accordingly, the thermal conductivity can be increased. The upper limit of the amount of the resin having a biphenyl skeleton is, for example, 15 mass % or less, preferably 10 mass % or less, and more preferably 7 mass % or less with respect to the entire thermally conductive paste. Accordingly, a balance between various properties of the thermally conductive paste, such as thermal conductivity and viscosity, can be achieved.

In this embodiment, the lower limit of the amount of the resin having a biphenyl skeleton and the amount of the (meth)acrylic monomer is, for example, 3 mass % or more, preferably 5 mass % or more, and more preferably 6 mass % or more with respect to the entire thermally conductive paste. Accordingly, the thermal conductivity and metal adhesion can be increased. The upper limit of the amount of the resin having a biphenyl skeleton and the amount of the (meth)acrylic monomer is, for example, 20 mass % or less, preferably 18 mass % or less, and more preferably 15 mass % or less with respect to the entire thermally conductive paste. Accordingly, a balance between various properties of the thermally conductive paste, such as thermal conductivity and curing properties, can be achieved.

In this embodiment, the lower limit of the amount of the (meth)acrylic monomer is, for example, 30 mass % or more, preferably 50 mass % or more, and more preferably 60 mass % or more with respect to 100 mass % of the total amount of the resin having a biphenyl skeleton and the (meth)acrylic monomer. Accordingly, the thermal conductivity and metal adhesion can be increased. The upper limit of the amount of the (meth)acrylic monomer is, for example, 95 mass % or less, preferably 90 mass % or less, and more preferably 88 mass % or less with respect to 100 mass % of the total amount of the resin having a biphenyl skeleton and the (meth)acrylic monomer. Accordingly, a balance between various properties of the thermally conductive paste, such as thermal conductivity and curing properties, can be achieved.

In this embodiment, the lower limit of the amount of the phenol resin having a biphenyl skeleton and the (meth)acrylic monomer is, for example, 3 mass % or more, preferably 5 mass % or more, and more preferably 6 mass % or more with respect to the entire thermally conductive paste. Accordingly, the thermal conductivity and metal adhesion can be increased. The upper limit of the amount of the phenol resin having a biphenyl skeleton and the (meth)acrylic monomer is, for example, 20 mass % or less, preferably 18 mass % or less, and more preferably 15 mass % or less with respect to the entire thermally conductive paste. Accordingly, a balance between various properties of the thermally conductive paste, such as thermal conductivity and curing properties, can be achieved.

(Curing Accelerator)

The thermally conductive paste may contain, for example, a curing accelerator.

In a case of using the epoxy resin as the thermosetting resin, as the curing accelerator, for example, one that accelerates the cross-linking reaction between the epoxy resin and the curing agent can be used. The curing accelerator may contain, for example, one or two or more selected from the group consisting of imidazoles, salts of triphenylphosphine or tetraphenylphosphine, amine compounds such as diazabicycloundecene and salts thereof, organic peroxides such as t-butyl cumyl peroxide, dicumyl peroxide, α,α′-bis(t-butylperoxy-m-isopropyl)benzene, 2,5-dimethyl-2,5-di(t-butylperoxy)hexane, and 2,5-dimethyl-2,5-di(t-butylperoxy)hexin-3. Among these, imidazole compounds such as 2-methylimidazole, 2-ethylimidazole, 2-phenylimidazole, 2-phenyl-4-methylimidazole, 2-phenyl-4-methyl-5-hydroxymethylimidazole, 2-phenyl-4,5-dihydroxymethylimidazole, 2-C₁₁H₂₃-imidazole, and adducts of 2-methylimidazole and 2,4-diamino-6-vinyltriazine are suitably used. Imidazole compounds having a melting point of 180° C. or higher are particularly preferable.

In a case where the cyanate resin is used as the thermosetting resin, as the curing accelerator, for example, those containing one or two or more selected from organometallic complexes such as zinc octylate, tin octylate, cobalt naphthenate, zinc naphthenate, and iron acetylacetonate, metal salts such as aluminum chloride, tin chloride, zinc chloride, and amines such as triethylamine and dimethylbenzylamine.

In this embodiment, the amount of the curing accelerator in the thermally conductive paste is preferably 0.05 mass % or more, and more preferably 0.1 mass % or more with respect to the entire thermally conductive paste. Accordingly, the curability of the thermally conductive paste can be improved. On the other hand, the amount of the curing accelerator in the thermally conductive paste is preferably 1 mass % or less, and more preferably 0.8 mass % or less with respect to the entire thermally conductive paste. Accordingly, the fluidity of the thermally conductive paste can be improved more effectively.

(Reactive Diluent)

The thermally conductive paste can contain, for example, a reactive diluent.

The reactive diluent may include, for example, one or more selected from monofunctional aromatic glycidyl ethers such as phenyl glycidyl ether, cresyl glycidyl ether, and t-butyl phenyl glycidyl ether, and aliphatic glycidyl ethers. Accordingly, it is possible to achieve the flatness of the adhesion layer while more effectively improving the application workability.

In this embodiment, the amount of the reactive diluent in the thermally conductive paste is preferably 3 mass % or more, and more preferably 4 mass % or more, with respect to the entire thermally conductive paste. Accordingly, the application workability of the thermally conductive paste and the flatness of the adhesion layer can be more effectively improved. On the other hand, the amount of the reactive diluent in the thermally conductive paste is preferably 20 mass % or less, and more preferably 15 mass % or less with respect to the entire thermally conductive paste. Accordingly, the improvement in the application workability can be achieved by suppressing the occurrence of dripping and the like during an application operation. In addition, it is also possible to improve the curability of the thermally conductive paste.

The thermally conductive paste of this embodiment may not contain a solvent. The term “solvent” mentioned here means a non-reactive solvent having no reactive group involved in the cross-linking reaction of the thermosetting resin contained in the thermally conductive paste. The expression “does not contain” means “does not substantially contain” and refers to a case where the amount of the non-reactive solvent is 0.1 mass % or less with respect to the entire thermally conductive paste.

On the other hand, the thermally conductive paste of this embodiment may contain a non-reactive solvent.

Examples of the non-reactive solvent include: hydrocarbon solvents including alkanes and cycloalkanes exemplified by butyl propylene triglycol, pentane, hexane, heptane, cyclohexane, and decahydronaphthalene, aromatic solvents such as toluene, xylene, benzene, and mesitylene, alcohols such as ethyl alcohol, propyl alcohol, butyl alcohol, pentyl alcohol, hexyl alcohol, heptyl alcohol, octyl alcohol, nonyl alcohol, decyl alcohol, ethylene glycol monomethyl ether, ethylene glycol monoethyl ether, ethylene glycol monopropyl ether, ethylene glycol monobutyl ether, propylene glycol monomethyl ether, propylene glycol monoethyl ether, propylene glycol monopropyl ether, propylene glycol monobutyl ether, methyl methoxy butanol, α-terpineol, β-terpineol, hexylene glycol, benzyl alcohol, 2-phenylethyl alcohol, isopalmityl alcohol, isostearyl alcohol, lauryl alcohol, ethylene glycol, propylene glycol, and glycerin; ketones such as acetone, methyl ethyl ketone, methyl isobutyl ketone, cyclohexanone, diacetone alcohol (4-hydroxy-4-methyl-2-pentanone), 2-octanone, isophorone (3,5,5-trimethyl-2-cyclohexen-1-one), and diisobutyl ketone (2,6-dimethyl-4-heptanone); esters such as ethyl acetate, butyl acetate, diethyl phthalate, dibutyl phthalate, acetoxyethane, methyl butyrate, methyl hexanoate, methyl octanoate, methyl decanoate, methyl cellosolve acetate, ethylene glycol monobutyl ether acetate, propylene glycol monomethyl ether acetate, 1,2-diacetoxyethane, tributyl phosphate, tricresyl phosphate, and tripentyl phosphate; ethers such as tetrahydrofuran, dipropyl ether, ethylene glycol dimethyl ether, ethylene glycol diethyl ether, ethylene glycol dibutyl ether, propylene glycol dimethyl ether, ethoxyethyl ether, 1,2-bis(2-diethoxy)ethane, and 1,2-bis(2-methoxyethoxy)ethane; ester-ethers such as 2-(2-butoxyethoxy)ethane acetate; ether-alcohols such as 2-(2-methoxyethoxy)ethanol; hydrocarbons such as n-paraffin, isoparaffin, dodecylbenzene, turpentine oil, kerosene, and light oil; nitriles such as acetonitrile or propionitrile; amides such as acetamide or N,N-dimethylformamide; and low molecular weight volatile silicone oils and volatile organic-modified silicone oils. These may be used singly or in combination of two or more.

The thermally conductive paste may contain other additives as necessary. Examples of other additives include coupling agents including silane coupling agents such as epoxysilane, mercaptosilane, aminosilane, alkylsilane, ureidosilane, vinylsilane, and sulfide silane, titanate coupling agents, aluminum coupling agents, and aluminum/zirconium coupling agents, colorants such as carbon black, solid components that enable low stress, such as silicone oil and silicone rubber, inorganic ion exchangers such as hydrotalcite, defoaming agents, surfactants, various polymerization inhibitors, and antioxidants. The thermally conductive paste can contain one or two or more of these additives.

The thermally conductive paste of this embodiment may be in the form of paste, for example.

In this embodiment, a method of preparing the thermally conductive paste is not particularly limited. However, for example, a paste-like resin composition can be obtained by premixing the above-mentioned components, thereafter kneading the mixture using three rolls, and defoaming the resultant in vacuum. At this time, it is possible to contribute to the improvement in long-term workability of the thermally conductive paste by appropriately adjusting the preparation conditions, such as performing premixing under reduced pressure.

An electronic device (semiconductor device 100) of this embodiment will be described.

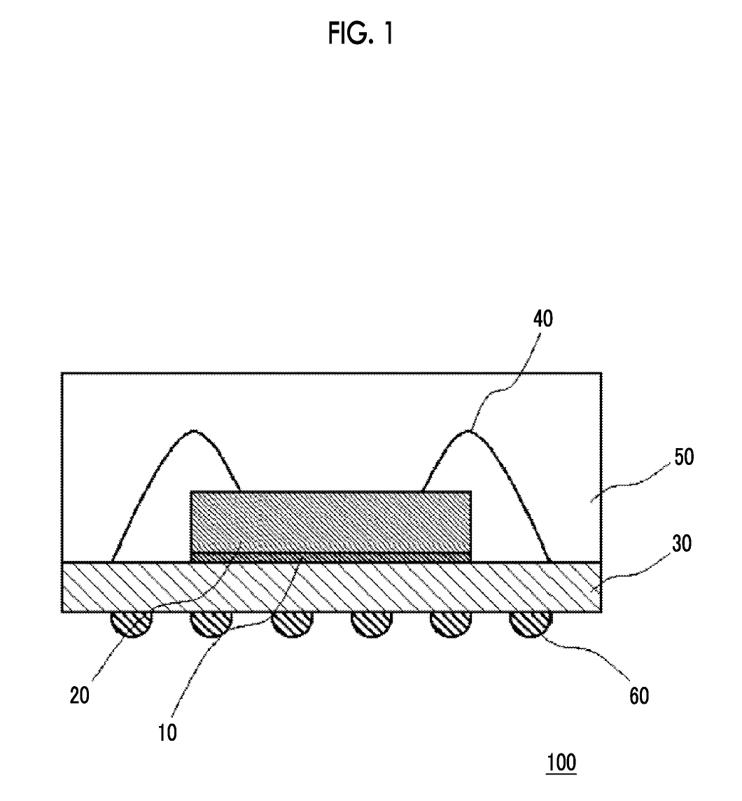

FIG. 1 is a cross-sectional view illustrating an example of the electronic device (semiconductor device 100) according to this embodiment.

The electronic device (semiconductor device 100) of this embodiment includes the cured product of the thermally conductive paste of this embodiment. For example, as illustrated in FIG. 1, the cured product can be used as an adhesion layer 10 for adhering a base material (substrate 30) to an electronic component (semiconductor element 20).

The semiconductor device 100 of this embodiment can include, for example, the substrate 30 and a semiconductor element 20 mounted on the substrate 30 with the adhesion layer 10 interposed therebetween. The semiconductor element 20 and the substrate 30 are electrically connected by, for example, a bonding wire 40. The semiconductor element 20 and the bonding wire 40 are sealed with a mold resin 50 formed by curing, for example, an epoxy resin composition.

The substrate 30 is, for example, a lead frame or an organic substrate. In FIG. 1, a case where the substrate 30 is an organic substrate is exemplified. In this case, for example, a plurality of solder balls 60 are formed on the rear surface of the substrate 30 opposite to the surface on which the semiconductor element 20 is mounted.

In the semiconductor device 100 according to this embodiment, the adhesion layer 10 is formed by curing the thermally conductive paste exemplified above. Therefore, it is possible to stably manufacture the semiconductor device 100.

In this embodiment, the thermally conductive paste can also be applied to the manufacturing of Mold Array Package (MAP) molded products. In this case, a plurality of adhesion layers are formed on a substrate by applying the thermally conductive paste to a plurality of regions on the substrate using a jet dispenser method, and thereafter a semiconductor element is mounted on each of the adhesion layers. Accordingly, the production efficiency can be further improved. Examples of the MAP molded products may include MAP-Ball Grid Arrays (BGA) and MAP-Quad Flat Non-Leaded Packages (QFN).

### Examples

Hereinafter, the present invention will be described in detail with reference to examples, but the present invention is not limited to the description of these examples at all.

(Preparation of Thermally Conductive Paste)

Regarding each of examples and comparative examples, components were mixed according to the formulation shown in Table 1, and were premixed at normal pressure for five minutes, and at a reduced pressure of 70 cmHg for 15 minutes. Next, the mixture was kneaded using three rolls and defoamed, thereby obtaining a thermally conductive paste. Details of each of the components in Table 1 are as follows. The unit in Table 1 is mass %.

(Thermosetting Resin)

Thermosetting resin 1: Bisphenol F type epoxy resin (SB-403S, manufactured by Nippon Kayaku Co., Ltd.)

Thermosetting resin 2: Epoxy resin having a biphenyl skeleton (solid at room temperature 25° C., YX-4000 K manufactured by Mitsubishi Chemical Corporation, weight-average molecular weight Mw: 354)

(Curing Agent)

Curing agent 1: Phenol resin having a biphenyl skeleton (solid at room temperature 25° C., biphenol manufactured by Honshu Chemical Industry Co., Ltd.)

Curing agent 2: Phenol resin having a bisphenol F skeleton (solid at room temperature 25° C., DIC-BPF manufactured by DIC Corporation)

Curing agent 3: Dicyandiamide (EH-3636AS manufactured by ADEKA Corporation)

(Thermally Conductive Filler)

Thermally conductive filler 1: Silver powder (AgC-2611 manufactured by Fukuda Metal Foil & Powder Co., Ltd., flake form)

Thermally conductive filler 2: Silver powder (AG2-1C manufactured by DOWA Electronics Materials Co., Ltd., spherical)

Thermally conductive filler 3: Silver powder (AgC-221A manufactured by Fukuda Metal Foil & Powder Co., Ltd., flake form)

D₅₀ and D₉₅ of the thermally conductive filler were measured by a laser diffraction scattering method.

(Acrylic Compound)

Acrylic compound 1: (Meth)acrylic monomer (1.6-hexanediol dimethacrylate, LIGHT ESTER 1.6 HX manufactured by Kyoeisha Chemical Co., Ltd.)

Acrylic compound 2: (Meth)acrylic monomer (ethylene glycol dimethacrylate, LIGHT ESTER EG, manufactured by Kyoeisha Chemical Co., Ltd.)

Acrylic compound 3: (Meth)acrylic monomer (2-ethylhexyl methacrylate, LIGHT ESTER EH, manufactured by Kyoeisha Chemical Co., Ltd.)

(Coupling Agent)

Coupling agent 1: tetrasulfide ditriethoxysilane (CABRUS 4, manufactured by Osaka Soda Co., Ltd.)

(Curing Accelerator)

Curing accelerator 1: Organic peroxide (PERKADOX BC manufactured by Kayaku Akzo Co., Ltd.)

Curing accelerator 2: Imidazole type (2-phenyl-4,5-dihydroxymethylimidazole, 2 PHZ manufactured by Shikoku Chemicals Corporation)

(Solvent)

Solvent 1: Ethylene glycol monobutyl ether acetate (BCSA manufactured by Tokyo Chemical Industry Co., Ltd.)

Solvent 2: Butyl propylene triglycol (BFTG manufactured by Nippon Nyukazai Co., Ltd.)

(Reactive Diluent)

Reactive diluent 1: Monoepoxy monomer (t-butyl phenyl glycidyl ether, SBT-H manufactured by Nippon Kayaku Co., Ltd.)

The following evaluations were conducted on the obtained thermally conductive paste. The evaluation results are shown in Table 1.

TABLE 1

| | | | Unit | Example 1 | Example 2 | Example 3 | Example 4 |
|---|---|---|---|---|---|---|---|
| Thermally | Thermosetting | Thermosetting | mass % | 6.60 | 6.39 | 6.60 | 6.60 |
| conductive | resin | resin 1 | | | | | |
| past | | Thermosetting | | | | | |
| | | resin 2 | | | | | |
| | Curing agent | Curing agent 1 | | 2.64 | 2.56 | 2.64 | 2.64 |
| | | Curing agent 2 | | 1.32 | 1.28 | 1.32 | 1.32 |
| | | Curing agent 3 | | | | | |
| | Reactive diluent | Reactive diluent 1 | | 2.64 | 2.56 | 2.64 | 2.64 |
| | Acrylic compound | Acrylic compound 1 | | 6.60 | 6.39 | | |
| | | Acrylic compound 2 | | | | 6.60 | |
| | | Acrylic compound 3 | | | | | 6.60 |
| | Coupling agent | Coupling agent 1 | | | | | |
| | Curing accelerator | Curing accelerator 1 | | 0.13 | 0.13 | 0.13 | 0.13 |
| | | Curing accelerator 2 | | 0.07 | 0.06 | 0.07 | 0.07 |
| | Solvent | Solvent 1 | | | | | |
| | | Solvent 2 | | | 0.64 | | |
| | Thermally | Thermally conductive | | 80.00 | | 80.00 | 80.00 |
| | conductive filler | filler 1 | | | | | |
| | | Thermally conductive | | | 80.00 | | |
| | | filler 2 | | | | | |
| | | Thermally conductive | | | | | |
| | | filler 3 | | | | | |

| | | | | |
|---|---|---|---|---|
| Total | 100.0 | 100.0 | 100.0 | 100.00 |

| Spreadability (wet spreading area after 8 hours at | | | 100 | 100 | 100 | 100 |
|---|---|---|---|---|---|---|
| 25° c.) | | | | | | |
| D: Thermally conductive filler D₅₀ | | μm | 4.5 | 0.85 | 4.5 | 4.5 |
| Thermally conductive filler D₉₅ | | μm | 10 | 3.1 | 10 | 10 |
| η: Viscosity of thermally conductive paste P not | | Pa · s | 0.13 | 0.07 | 0.08 | 0.11 |
| containing thermally conductive filler at BF100 rpm | | | | | | |
| Degree of sedimentation | | [10⁻¹² · m³ · s/kg] | 155.8 | 10.3 | 253.1 | 184.1 |
| (S = D²/η) | | | | | | |
| Room temperature storability (separation after 48 | | | ∘ | ∘ | ∘ | ∘ |
| hours at 25° c.) | | | | | | |
| Thermal conductivity | | W/mK | 10 | 14 | 15 | 6 |
| Ejection stability (stringiness occurrence ratio) | | % | 0 | 0 | 0 | 0 |
| Die shear strength after | Ag plated | N/1 mm² | 19 | 22 | 18 | 21 |
| moisture absorption | Au plated | N/1 mm² | 31 | 33 | 27 | 31 |

| | | | | | | Comparative | Comparative |
|---|---|---|---|---|---|---|---|
| | | | Example 5 | Example 6 | Example 7 | Example 1 | Example 2 |
| Thermally | Thermosetting | Thermosetting | 8.23 | 7.07 | 4.56 | 9.95 | 5.07 |
| conductive | resin | resin 1 | | | | | |
| past | | Thermosetting | | | 3.04 | | |
| | | resin 2 | | | | | |
| | Curing agent | Curing agent 1 | 3.29 | 1.41 | | 3.98 | |
| | | Curing agent 2 | 1.65 | 1.41 | 1.52 | 1.99 | 0.78 |
| | | Curing agent 3 | | | | | 0.16 |
| | Reactive diluent | Reactive diluent 1 | 3.29 | 2.83 | 3.04 | 3.98 | 2.73 |
| | Acrylic compound | Acrylic compound 1 | | 7.07 | 7.60 | | |
| | | Acrylic compound 2 | 3.29 | | | | |
| | | Acrylic compound 3 | | | | | |
| | Coupling agent | Coupling agent 1 | | | | | 0.16 |
| | Curing accelerator | Curing accelerator 1 | 0.16 | 0.14 | 0.15 | | |
| | | Curing accelerator 2 | 0.08 | 0.07 | 0.08 | 0.10 | 0.16 |
| | Solvent | Solvent 1 | | | | | 1.95 |
| | | Solvent 2 | | | | | |
| | Thermally | Thermally conductive | 80.00 | 80.00 | 80.00 | 80.00 | |
| | conductive filler | filler 1 | | | | | |
| | | Thermally conductive | | | | | |
| | | filler 2 | | | | | |
| | | Thermally conductive | | | | | 89.00 |
| | | filler 3 | | | | | |

| | | | | | |
|---|---|---|---|---|---|
| Total | 100.00 | 100.00 | 100.0 | 100.0 | 100.00 |

| Spreadability (wet spreading area after 8 hours at | | 100 | 100 | 100 | 100 | 85 |
|---|---|---|---|---|---|---|
| 25° c.) | | | | | | |
| D: Thermally conductive filler D₅₀ | | 4.5 | 4.5 | 4.5 | 4.5 | 8.5 |
| Thermally conductive filler D₉₅ | | 10 | 10 | 10 | 10 | 18 |
| η: Viscosity of thermally conductive paste P not | | 0.43 | 0.09 | 0.07 | 2.79 | 0.08 |
| containing thermally conductive filler at BF100 rpm | | | | | | |
| Degree of sedimentation | | 47.1 | 225.0 | 289.3 | 7.3 | 903.1 |
| (S = D²/η) | | | | | | |
| Room temperature storability (separation after 48 | | ∘ | ∘ | ∘ | ∘ | x |
| hours at 25° c.) | | | | | | |
| Thermal conductivity | | 6 | 8 | 9 | 2 | 10 |
| Ejection stability (stringiness occurrence ratio) | | 0 | 0 | 0 | 96 | 14 |
| Die shear strength after | Ag plated | 14 | 18 | 16 | 4 | 14 |
| moisture absorption | Au plated | 22 | 26 | 16 | 4 | 26 |

(η: Viscosity of Resin Not Containing Thermally Conductive Filler)

A thermally conductive paste P not containing the thermally conductive filler was prepared without using the thermally conductive filler while using the mixing composition and mixing ratio shown in Table 1. Using a Brookfield viscometer (HADV-3 Ultra, Spindle CP-51 (angle 1.565°, radius 1.2 cm)), the viscosity (η) of the thermally conductive paste P immediately after being prepared was measured under conditions of 25° C. and 100 rpm. The unit of the viscosity is Pa·S. The evaluation results are shown in Table 1.

The degree of sedimentation of the thermally conductive filler in the thermally conductive paste in Table 1 was referred to as S=D²/η. In the degree of sedimentation S, the average particle size D₅₀ of the thermally conductive filler was referred to as D, and the viscosity of the thermally conductive paste P excluding the thermally conductive filler was referred to as η.

(Thermal Conductivity)

Using the obtained thermally conductive paste, a disc-shaped test piece of 1 cm square and 1 mm thickness was produced (curing conditions were 175° C. and 4 hours, but the temperature was increased to 175° C. from room temperature over 60 minutes). The thermal conductivity (=α×Cp×ρ) was calculated from the thermal diffusivity (α) measured by a laser flash method (t1/2 method), the specific heat (Cp) measured by a DSC method, and the density (ρ) measured according to JIS-K-6911, and a thermal conductivity of 5 W/m·K was evaluated as acceptable. The unit of the thermal conductivity is W/m·K. The evaluation results are shown in Table 1.

(Room Temperature Storability)

A 5-cc syringe (manufactured by Musashi Engineering, Inc.) was filled with the obtained thermally conductive paste, and was capped with an inner cap and an outer cap, was then set in a syringe stand, and was treated in a thermostat at 25° C. for 48 hours. Thereafter, the external appearance was visually checked, and the presence or absence of separation of the thermally conductive paste was checked. In Table 1, a case with no separation was indicated by O, and a case with separation was indicated by X. The evaluation results are shown in Table 1.

(Spreadability)

The obtained thermally conductive paste was applied to the surface of a lead frame made of copper so as to intersect diagonally. Next, the resultant was statically left at room temperature 25° C. for 8 hours. Next, a silicon bare chip (thickness 0.525 mm) having a surface of 2 mm×2 mm was mounted on the lead frame through the thermally conductive paste under a load of 50 g and 50 ms and then observed with an X-ray apparatus. By binarizing the image obtained by X-ray observation, the ratio (%) of the wet spreading area of the thermally conductive paste to the surface area of 100% of the silicon bare chip was calculated. The evaluation results are shown in Table 1.

(Ejection Stability (Stringiness Occurrence Ratio))

The obtained thermally conductive paste filling a 5-cc syringe (manufactured by Musashi Engineering, Inc.) was set in Shotmaster 300 (manufactured by Musashi Engineering, Inc.), and dot application (280 dots) was performed at an ejection pressure of 100 kPa for an ejection time of 100 ms. Thereafter, the number of dots of which the application shape was not circular (the number of stringiness occurrences) was visually checked, and the ratio thereof to 280 dots was calculated as a stringiness occurrence ratio (%). The evaluation results are shown in Table 1.

(Die Shear Strength after Moisture Absorption)

Using the obtained thermally conductive paste, a Ag plated chip (length×width×thickness: 2 mm×2 mm×0.35 mm) was mounted on a support Ag plated frame (a copper lead frame plated with Ag, manufactured by Shinko Electric Industries Co., Ltd.), and was cured in a curing temperature profile of 175° C. and 60 minutes (temperature rising rate 5° C./min from 25° C. to 175° C.) using an oven, whereby sample 1 was prepared.

In addition, using the obtained thermally conductive paste, a Au plated chip (length×width×thickness: 2 mm×2 mm×0.35 mm) was mounted on a Au plated chip (length×width×thickness: 5 mm×5 mm×0.35 mm), and was cured in a curing temperature profile of 175° C. and 60 minutes (temperature rising rate 5° C./min from 25° C. to 175° C.) using an oven, whereby sample 2 was prepared.

Samples 1 and 2 obtained were subjected to a moisture absorption treatment for 72 hours under conditions of 85° C. and humidity 85%, and the hot die shear strength at 260° C. was measured (unit: N/1 mm²).

The evaluation results are shown in Table 1.

It could be seen that the thermally conductive pastes of Examples 1 to 7 are superior in room temperature storability (storage stability) to Comparative Example 2, and are superior in ejection stability (handleability) to Comparative Examples 1 and 2. In addition, it could be seen that the thermally conductive pastes of Examples 1 to 7 are also excellent in thermal conductivity and die shear strength (metal adhesion).

This application claims priority to Japanese Patent Application No. 2016-213664 filed on Oct. 31, 2016, the disclosure of which is incorporated herein in its entirety.

1. A thermally conductive paste comprising:
a thermosetting resin; and
a thermally conductive filler,
wherein a ratio of a wet spreading area calculated by the following measurement method is 90% or more, and
wherein when an average particle size D₅₀ of the thermally conductive filler is referred to as D, a viscosity of the thermally conductive paste excluding the thermally conductive filler at room temperature 25° C. is referred to as η, and a degree of sedimentation of the thermally conductive filler in the thermally conductive paste is referred to as S=D²/η, S is 8.0 [10⁻¹²·m³·s/kg] or more and 802.8 [10⁻¹²·m³·s/kg] or less;
(Measurement Method of Wet Spreading Area)
wherein the measurement method of wet spreading area is as follows:
the thermally conductive paste is applied to a surface of a lead frame using a 5-cc syringe from one end to the other along two diagonals line connecting diagonal 2 mm×2 mm square so as to that the two application lines intersect; next, the resultant is statically left at room temperature 25° C. for 8 hours; next, a 2 mm×2 mm silicon bare chip having a thickness 0.525 mm is mounted on the lead frame through the thermally conductive paste under a load of 50 g and 50 ms, and thereafter the ratio of the wet spreading area of the thermally conductive paste to the surface of the silicon bare chip is calculated.

2. The thermally conductive paste according to claim 1,
wherein a thermal conductivity of a cured product of the thermally conductive paste is 5 W/mK or more.

3. The thermally conductive paste according to claim 1,
wherein an average particle size D₅₀ of the thermally conductive filler is 0.1 μm or more and 10 μm or less.

4. The thermally conductive paste according to claim 1,
wherein D₉₅ of the thermally conductive filler is 15 μm or less.

5. The thermally conductive paste according to claim 1,
wherein the thermally conductive filler contains a metal, an oxide, or a nitride.

6. The thermally conductive paste according to claim 1,
wherein an amount of the thermally conductive filler is 50 mass % or more and 88 mass % or less with respect to the entire thermally conductive paste.

7. The thermally conductive paste according to claim 1,
wherein a weight-average molecular weight of the thermosetting resin is 100 or more and 500 or less.

8. The thermally conductive paste according to claim 1,
wherein the thermosetting resin contains a resin having a biphenyl skeleton.

9. The thermally conductive paste according to claim 1,
wherein the thermosetting resin contains an epoxy resin.

10. The thermally conductive paste according to claim 1, further comprising:
a curing agent.

11. The thermally conductive paste according to claim 1, further comprising:
an acrylic compound.

12. The thermally conductive paste according to claim 1, further comprising:
a reactive diluent.

13. The thermally conductive paste according to claim 1, further comprising:
a curing accelerator.

14. The thermally conductive paste according to claim 1,
wherein a solvent is not contained.

15. An electronic device comprising:
a cured product of the thermally conductive paste according to claim 1.
